(19) United States
(12) Patent Application Publication
(10) Pub. No.: US 2015/0153112 A1
(43) Pub. Date: Jun. 4, 2015

(54) HEAT CONDUCTION DEVICE

(71) Applicant: ROBO-TEAM LTD., Tel Aviv (IL)

(72) Inventors: Gregory Heifets, Rehovot (IL); Daniel Cantor, Tel Aviv (IL); Mark Vaynberg, Petach Tikva (IL); Eli Shukrun, Lehavim (IL); Yosi Wolf, Tel Aviv (IL); Elad Levy, Tel Aviv (IL)

(21) Appl. No.: 14/301,615

(22) Filed: Jun. 11, 2014

(30) Foreign Application Priority Data
Dec. 1, 2013 (IL) 229744

(51) Int. Cl. F28F 3/00; F28F 9/00; F28F 21/06

(52) U.S. Cl. CPC F28F 3/00; F28F 21/06; F28F 9/005

(57) ABSTRACT

There is provided, in accordance with an embodiment, a ground robot comprising: a mounting bracket configured for mounting of electronic equipment of the ground robot; a heat conduction device configured to evacuate heat from the electronic equipment to the environment, said heat conduction device comprising: a flexible heat-resistant sheet; a heat-conducting sheet wrapped at least partially around said flexible heat-resistant sheet.

### FIELD OF THE INVENTION

The invention relates to heat conduction devices.

### BACKGROUND

Electronic devices commonly generate a considerable amount of residue heat. Among the major heat generators are processors, motors, electro-mechanical parts, etc. When the residue heat reaches high temperatures, it might start to physically harm various components of the electronic device. Accordingly, many devices have been suggested for evacuating the heat from the electronic device to the environment. These devices are usually divided into passive and active devices, with the passive devices not requiring electrical power for operation, while the active devices do.

Passive devices include, for example, various heat exchangers, heat conductors, heat pipes, heat sinks and the like. Exemplary active devices include fans, air conditioners, fluid coolers, and more.

The foregoing examples of the related art and limitations related therewith are intended to be illustrative and not exclusive. Other limitations of the related art will become apparent to those of skill in the art upon a reading of the specification and a study of the figures.

### SUMMARY

The following embodiments and aspects thereof are described and illustrated in conjunction with systems, tools and methods which are meant to be exemplary and illustrative, not limiting in scope.

There is provided, in accordance with an embodiment, a ground robot comprising: a mounting bracket configured for mounting of electronic equipment of the ground robot; a heat conduction device configured to evacuate heat from the electronic equipment to the environment, said heat conduction device comprising: a flexible heat-resistant sheet; a heat-conducting sheet wrapped at least partially around said flexible heat-resistant sheet.

There is further provided, in accordance with an embodiment, use of a heat conduction device for evacuating heat from electronic equipment of a ground robot to the environment, said heat conduction device comprising: a flexible heat-resistant sheet configured to prevent damage to the electronic equipment by damping shocks; and a heat-conducting sheet wrapped at least partially around said flexible heat-resistant sheet.

In some embodiments: said mounting bracket comprises a heat sink; and said heat conduction device is mounted over said heat sink.

In some embodiments, said heat sink is made of anodized Aluminum.

In some embodiments, said mounting bracket comprises a plurality of poles for mounting the electronic equipment over said heat conduction device.

In some embodiments, said flexible heat-resistant sheet is made of a porous elastomer.

In some embodiments, said flexible heat-resistant sheet is made of EPDM (ethylene propylene diene monomer) rubber.

In some embodiments, said flexible heat-resistant sheet is cubical.

In some embodiments, said heat-conducting sheet is wrapped around four facets of said flexible heat-resistant sheet.

In some embodiments, said heat-conducting sheet is rectangular when spread out.

In some embodiments, said heat-conducting sheet is a tin-coated copper mesh.

In some embodiments, the ground robot further comprises at least one thermal pad interfacing between at least one external surface of said heat conduction device and the electronic equipment.

In some embodiments, the ground robot further comprises an adhesive on one or more surfaces of said at least one thermal pad.

In some embodiments, said at least one thermal pad is made of a blend of silicone and a ceramic.

In some embodiments: said mounting bracket comprises a heat sink; and said heat conduction device is mounted over said heat sink.

In some embodiments, said at least one thermal pad comprises: a first thermal pad interfacing between a first external surface of said heat conduction device and the electronic equipment; and a second thermal pad interfacing between a second external surface of said heat conduction device and said heat sink, wherein said first and second external surfaces of said heat conduction device are opposing surfaces.

In addition to the exemplary aspects and embodiments described above, further aspects and embodiments will become apparent by reference to the figures and by study of the following detailed description.

### BRIEF DESCRIPTION OF THE FIGURES

Exemplary embodiments are illustrated in referenced figures. Dimensions of components and features shown in the figures are generally chosen for convenience and clarity of presentation and are not necessarily shown to scale. The figures are listed below.

FIG. 1A shows an exemplary flexible heat conduction device in perspective view;

FIG. 1B shows the exemplary flexible heat conduction device in cross-sectional view;

FIG. 2A shows a mounting bracket of a ground robot in a top perspective view;

FIG. 2B shows the mounting bracket of a ground robot in a bottom perspective view; and

FIG. 3 shows a graph summarizing experimental results.

### DETAILED DESCRIPTION

A flexible heat conduction device and a ground robot comprising the same are disclosed herein. Advantageously, the flexible heat conduction device may be capable of effectively evacuating heat from inside the robot to the environment, while simultaneously protecting delicate electronic equipment of the robot from vibration and shock.

Ground vehicles face many challenges when attempting mobility. Terrain can vary widely, including, for example, loose and shifting materials, obstacles, vegetation, limited width openings, limited height openings, steps, uneven surfaces, tunnels, holes and the like. A variety of mobility configurations have been suggested, to transverse difficult terrain. These configurations include legs, wheels, tracks and more. Still, a ground robot travelling over various terrain types is subject to substantial amounts of vibration and shock. These can ultimately lead to damage to various components of the robot, among which is its electronic equipment. This equipment includes, for example, one or more integrated circuits, printed circuit boards (PCBs), electrical motors, electrical actuators, etc.

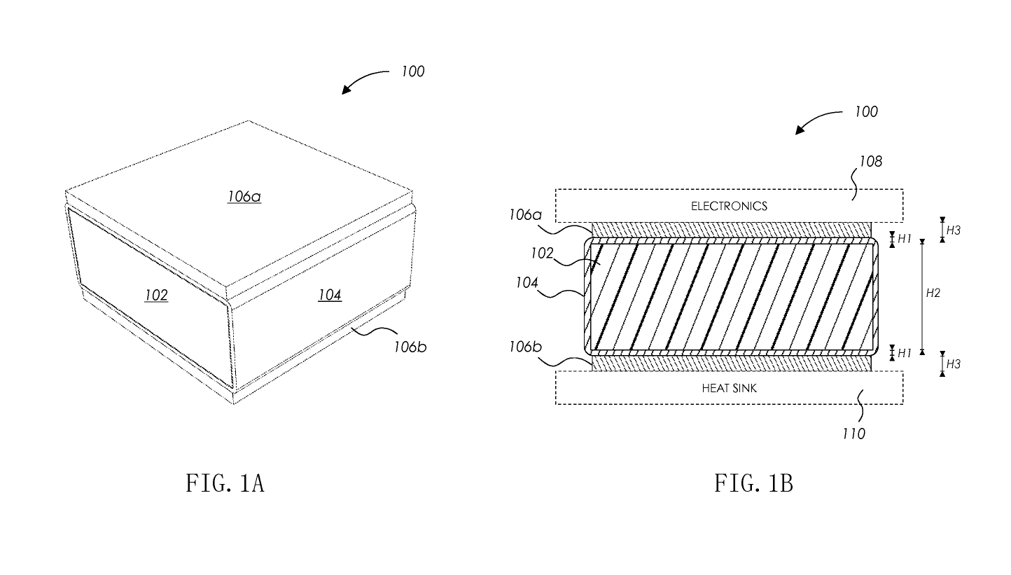

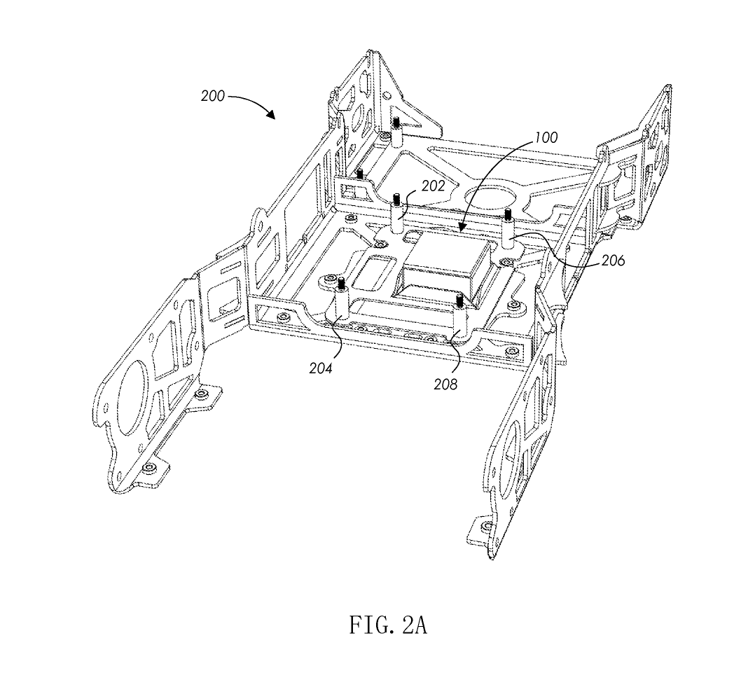

Reference is now made to FIGS. 1A and 1B, which show an exemplary flexible heat conduction device (or simply “device”) 100, in accordance with an embodiment. Device 100 is shown having a cubical shape. However, those of skill in the art will recognize that other shapes (not shown) might as well be possible, as long as they are constructed in accordance with the principles of the present embodiment, discussed below.

Device 100 may be configured to evacuate heat from electronic equipment (shown schematically at 108) of a ground robot (not shown) to the environment. Accordingly, device 100 may be structured to transfer heat from one side thereof, located proximally to electronic equipment 108, to another side thereof, located distally to the electronic equipment. The distally-located side of device 100 may either be exposed, at least partially, to the environment external to the robot, or be in contact with an intermediary which is exposed, at least partially, to the environment external to the robot.

Device 100 may include a heat-conducting sheet 104 which is wrapped, at least partially, around a flexible heat-resistant sheet 102. The flexibility of heat-resistant sheet 102 serves to absorb and/or dampen various vibrations and/or shocks occurring as a result of the robot's interaction with its surroundings. Heat-resistant sheet 102 may be made, for example, from a porous elastomer, capable of compressing upon exertion of external power, and also capable of withstanding, without deformation, the characteristic temperatures of electronic equipment 108 (commonly in the range of 70-100 degrees Celsius, but optionally lower or higher). A suitable exemplary material is EPDM (ethylene propylene diene monomer) rubber.

Heat-resistant sheet 102 may be shaped as a cube having a height H2, although those of skill in the art will recognize that other shapes (not shown) might as well be possible, as long as they are constructed in accordance with the principles of the present embodiment, discussed herein.

Heat-conducting sheet 104 is optionally wrapped around four facets of heat-resistant sheet 102. Accordingly, heat-conducting sheet 104 may have an essentially rectangular shape when spread out, having a length which is sufficient to cover the four facets in sequence. Heat-conducting sheet 104 may cover the entirety of the four facets, or at least a substantial portion of the four facets.

Heat-conducting sheet 104 may have a thickness H1 and be made of one or more materials with relatively high thermal conductivity, such as metal. This allows for heat to be conducted, through heat-conducting sheet 104, from one side of device 100 (e.g. from electronic equipment 108) to the opposing side of the device (e.g. to a heat sink 110). As an example, heat-conducting sheet 104 may be made of tin-coated copper. Specifically, heat-conducting sheet 104 may be a mesh of tin-coated copper threads. This endows heat-conducting sheet 104 with a certain elasticity, such that, together with heat-resistant sheet 102, they construct a flexible structure able to compress when external force is exerted, and expand to its original shape when the force ceases.

In one embodiment, one or both sides of heat-conducting sheet 104 may be in direct contact with electronic equipment 108 and/or heat sink 110, respectively. In another embodiment, device 100 may include a thermal pad on one or both sides of heat-conducting sheet 104, for enhancing the interface between the heat-conducting sheet and electronic equipment 108 and/or heat sink 110. For illustrative reasons, FIGS. 1A-B show two thermal pads, a top thermal pad 106a and a bottom thermal pad 106b. Each of thermal pads 106a-b may be made of an easily deformable material exhibiting good thermal conductivity. The deformability of thermal pads 106a-b allows them to form a relatively large surface area which contacts electronic equipment 108 and/or heat sink 110, respectively. Namely, each of thermal pads 106a-b may deform, on one side, to the surface profile of heat-conducting sheet 104, and on the other side to the surface profile of electronic equipment 108 and/or heat sink 110, respectively. These surface profiles may be relatively rough.

Thermal pads 106a-b may be made, from example, of a blend of silicone and a ceramic. Thermal pads 106a-b may each include an adhesive on their opposing surface areas, in order to better secure them to heat-conducting sheet 104 on one side, and to electronic equipment 108 and heat sink 110, respectively, on the other side. Each of thermal pads 106a-b may have a same thickness H3. In a different embodiment (not shown), each of the thermal pads has a different thickness.

In an embodiment, the ratio between H1, H2 and H3 is approximately 1:20:3, respectively, wherein the term “approximately” is defined as±20% for each of the three values.

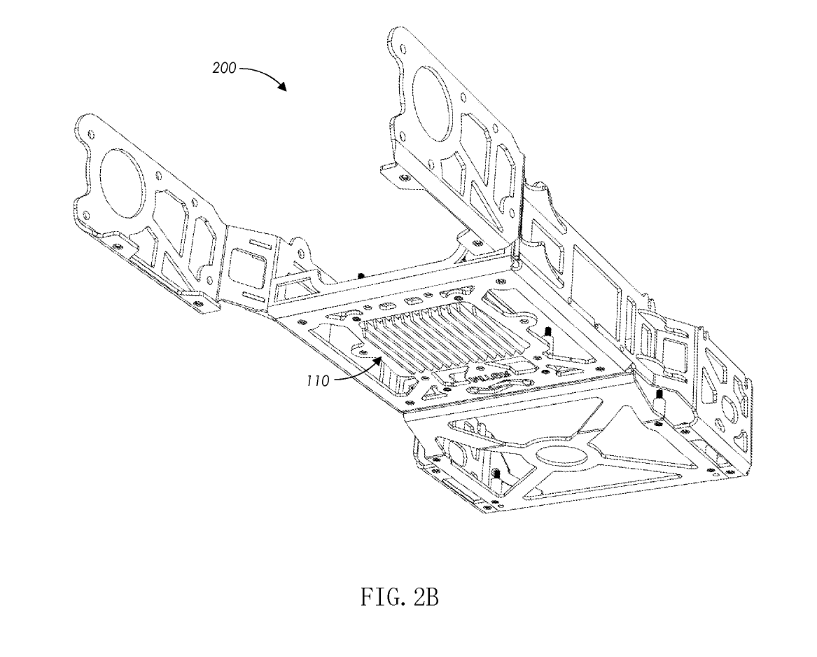

Reference is now made to FIG. 2A, which shows a mounting bracket 200 of a ground robot (its remaining parts are not shown), in a top perspective view. Mounting bracket 200 may be configured for mounting of electronic equipment of the ground robot. To this end, mounting bracket 200 may be equipped with a plurality of elevated connectors, such as pillars 202, 204, 206 and 208. A narrower tip of each of pillars 202, 204, 206 and 208 may be threaded, for example, through suitable holes in PCBs or other electronic equipment (not shown). The narrower tip may include an external thread. After a PCB, for example, is threaded onto the narrower tips of pillars 202, 204, 206 and 208, a nut (not shown) may be threaded onto each narrower tip, such that the PCB is delimited between the nut on one side and a broader bottom of each of the pillars on the other side. The nuts, however, may not be tightened completely, to allow some vertical freedom of movement of the PCB. This is the movement which exerts force on device 100, shown here suitably positioned on mounting bracket 200. When the robot incurs shock or vibration, they are not transferred from mounting bracket 200 to the PCB directly, but rather through device 100.

The shape of mounting bracket 200 may be, generally, of a horizontal surface delimited between two erecting walls. Of course, the precise shape of mounting bracket 200 may be much more complex, to fit various units of electronic equipment and to allow for connection to many other parts of the robot.

It should be noted that the position of device 100 on mounting bracket 200 is shown here only as one possible example. Device 100, or a plurality of such devices, may be present in one or more other locations on mounting bracket 200 or a different mounting bracket. The size of such one or more devices may be such that they extend over a larger area of mounting bracket 200 or a different mounting bracket. For example, one such device may fit below multiple pieces of electronic equipment.

Lastly, reference is made to FIG. 2B, which shows mounting bracket 200 in a bottom perspective view. In this view, heat sink 110 is visible. Heat sink 110 may be mounted to mounting bracket 200 from below, directly beneath device 100 (not seen in this view). In some embodiments, heat sink 110 extends to cover at least the entire bottom area of device 100. In other embodiments, heat sink 110 extends to cover an area smaller than the bottom area of device 100.

In some embodiments, heat sink 110 is centrally aligned with device 100, while in some heat sink 110 is not centrally aligned with device 100.

Heat sink 110 may be constructed and operative as known in the art. Heat sink 110 may be made of a solid metallic body having good thermal conductivity. For example, it may be made of Aluminum, whether anodized or not. The solid metallic body may include multiple rays, in a radiator configuration, to enlarge the surface area of the heat sink.

### EXPERIMENTAL RESULTS

The efficacy of the present heat conduction device has been assessed experimentally. In this experiment, the heat conduction device was mounted in a ground robot available from Roboteam Ltd., of Tel Aviv, Israel, under the name MTGR (Micro Tactical Ground Robot). A specification of the MTGR is available online, at http://www.robo-team.com/uploads//Brochures/MTGR%20-%20Brochure_Website %20111813.pdf.

The heat conduction device of the experiment measured 18.7 mm (thickness)×35 mm (length)×36.7 mm (width). The device included an EPDM cube serving as a heat-resistant sheet. The EPDM cube was wrapped with a heat-conducting sheet made of a mesh of tin-coated copper threads. The overall structure of the experimental heat conduction device was as shown in FIGS. 1A-B.

The EPDM cube had a thickness of about 13.3 millimeters (mm), corresponding to H2 of FIG. 1B. The EPDM cube had a length of 31 mm and a width of 32.6 mm.

The heat-conducting sheet, in turn, had a thickness of 0.7 mm, corresponding to H1 of FIG. 1A. It had a length of 100 mm and a width of 35 mm. When wrapped around the EPDM cube, the heat-conducting sheet fully covered four facets of the EPDM cube.

Two thermal pads, made of a blend of silicone and ceramic, were adhesively coupled to the heat conducting sheet—one from the top and one from the bottom. Each of the thermal pads had approximately the same width and length of the EPDM cube, and a thickness of 2 mm, corresponding to H3 of FIG. 1B.

The heat conduction device was mounted on a mounting bracket of the MTGR, the mounting bracket having an overall structure as shown in FIGS. 2A-B. The heat conduction device was mounted at the location shown in FIG. 2A. The mounting bracket had an anodized Aluminum heat sink coupled to its bottom surface, below the heat conduction device, as shown in FIG. 2B.

A circuit board of the MTGR was mounted over the heat conduction device, in contact with the top thermal pad of the device. The circuit board was the MTGR's wireless communication module, which is the Wave Relay MANET Datalink Gen3 Integration Board available from Persistent Systems, LLC, of New York City, USA. This board is known to be sensitive to heat; its operation is degraded or even fails at high temperatures. According to its specifications, the board's operating temperature upper limit is 85 degrees Celsius.

The MTGR was positioned on a stand, inside a room having an ambient temperature of 40 degrees Celsius. Then, the various systems of the MTGR, such as its drive system, communication system, etc. have been continuously activated. The temperature of the circuit board was logged during the activity. Wireless communication with the MTGR began deteriorating after 75 minutes of activity, indicating that the circuit board stopped functioning properly. Its temperature at this point reached 85 degrees Celsius.

Following this experiment, the circuit board was tested for structural and operational damage. No damage was detected, and the same circuit board was functional in operations performed thereafter.

As a control group, an MTGR lacking a heat conduction device was operated under the same conditions. The mounting bracket of this MTGR included an anodized Aluminum heat sink but lacked a heat conduction device between the heat sink and the circuit board. In this experiment, the temperature of the circuit board reached 85 degrees already after 40 minutes, and wireless communication began deteriorating at 49 minutes, as the temperature reached 87 degrees Celsius.

In conclusion, the heat conduction device improved the operational time of the MTRG by approximately 53% (49 minutes versus 75 minutes). Advantageously, the heat conduction device achieved its heat evacuation role while being flexible enough so as not to physically harm the circuit board.

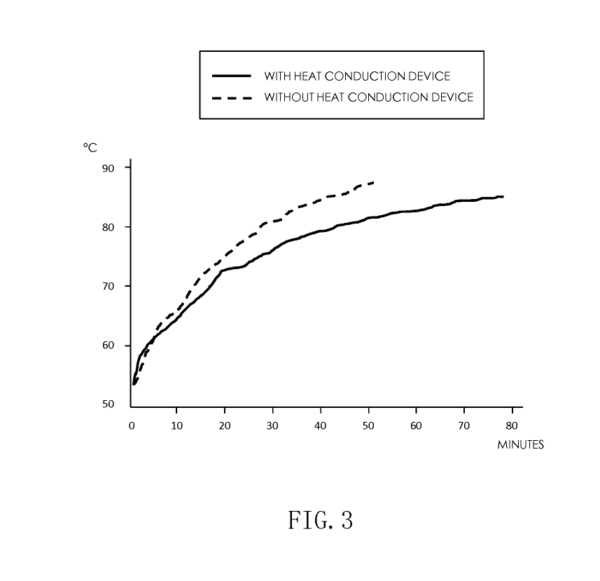

FIG. 3 shows a graph which summarizes the experimental results. The graph shows the temperature of the circuit board as a function of time.

In the description and claims of the application, each of the words “comprise” “include” and “have”, and forms thereof, are not necessarily limited to members in a list with which the words may be associated. In addition, where there are inconsistencies between this application and any document incorporated by reference, it is hereby intended that the present application controls.

What is claimed is:

1. A ground robot comprising:
a mounting bracket configured for mounting of electronic equipment of the ground robot;
a heat conduction device configured to evacuate heat from the electronic equipment to the environment, said heat conduction device comprising:
(a) a flexible heat-resistant sheet;
(b) a heat-conducting sheet wrapped at least partially around said flexible heat-resistant sheet.

2. The ground robot according to claim 1, wherein:
said mounting bracket comprises a heat sink; and
said heat conduction device is mounted over said heat sink.

3. The ground robot according to claim 2, wherein said heat sink is made of anodized aluminum.

4. The ground robot according to claim 2, wherein said mounting bracket comprises a plurality of poles for mounting the electronic equipment over said heat conduction device.

5. The ground robot according to claim 1, wherein said flexible heat-resistant sheet is made of a porous elastomer or of EPDM (ethylene propylene diene monomer) rubber.

6. The ground robot according to claim 1, wherein said flexible heat-resistant sheet is cubical and is wrapped around four facets of said flexible heat-resistant sheet.

7. The ground robot according to claim 6, wherein said heat-conducting sheet is rectangular when spread out.

8. The ground robot according to claim 1, wherein said heat-conducting sheet is a tin-coated copper mesh.

9. The ground robot according to claim 1, further comprising at least one thermal pad interfacing between at least one external surface of said heat conduction device and the electronic equipment.

10. The ground robot according to claim 9, further comprising an adhesive on one or more surfaces of said at least one thermal pad.

11. The ground robot according to claim 9, wherein said at least one thermal pad is made of a blend of silicone and a ceramic.

12. The ground robot according to claim 9, wherein said at least one thermal pad comprises:
a first thermal pad interfacing between a first external surface of said heat conduction device and the electronic equipment; and
a second thermal pad interfacing between a second external surface of said heat conduction device and said heat sink,
wherein said first and second external surfaces of said heat conduction device are opposing surfaces.

13. Use of a heat conduction device for evacuating heat from electronic equipment of a ground robot to the environment, said heat conduction device comprising:
a flexible heat-resistant sheet configured to prevent damage to the electronic equipment by damping shocks; and
a heat-conducting sheet wrapped at least partially around said flexible heat-resistant sheet.

14. The use according to claim 13, wherein:
said mounting bracket comprises a heat sink; and
said heat conduction device is mounted over said heat sink.

15. The use according to claim 13, wherein said flexible heat-resistant sheet is made of a porous elastomer or of EPDM (ethylene propylene diene monomer) rubber.

16. The use according to claim 13, wherein said flexible heat-resistant sheet is cubical and is wrapped around four facets of said flexible heat-resistant sheet.

17. The use according to claim 16, wherein said heat-conducting sheet is rectangular when spread out.

18. The use according to claim 13, wherein said heat-conducting sheet is a tin-coated copper mesh.

19. The use according to claim 13, wherein said heat conduction device further comprises at least one thermal pad interfacing between at least one external surface of said heat conduction device and the electronic equipment.

20. The use according to claim 19, wherein said at least one thermal pad comprises:
a first thermal pad interfacing between a first external surface of said heat conduction device and the electronic equipment; and
a second thermal pad interfacing between a second external surface of said heat conduction device and said heat sink,
wherein said first and second external surfaces of said heat conduction device are opposing surfaces.
